(19) United States
(12) Patent Application Publication
(10) Pub. No.: US 2024/0123653 A1
(43) Pub. Date: Apr. 18, 2024

(54) EASILY-RELEASABLE CONCRETE TEST MOULD WITH INNER WALL HAVING ULTRA-HYDROPHOBIC/ULTRA-SMOOTH PERFORMANCE AND PREPARATION METHOD THEREOF

(71) Applicant: TaiShan University, Tai'an City (CN)

(72) Inventors: Qing WANG, Tai'an City (CN); Shuangshuang XU, Tai'an City (CN); Rui ZHANG, Tai'an City (CN)

(21) Appl. No.: 18/463,702

(22) Filed: Sep. 8, 2023

(30) Foreign Application Priority Data
Oct. 18, 2022 (CN) 202211273362.9

(51) Int. Cl. B28B 7/36; B28B 7/34

(52) U.S. Cl. CPC B28B 7/36; B28B 7/346

(57) ABSTRACT

A preparation method for an easily-releasable concrete test mould with an inner wall having ultra-hydrophobic/ultra-smooth performance includes spin-coating a negative photoresist and obtaining a substrate with an inner wall having inverted-trapezoid microstructures by ultraviolet lithography; depositing a metal layer by vacuum evaporation; removing the metal layer on an upper surface of the inverted trapezoid microstructures of the inner wall of the substrate; obtaining a micro-nano hierarchical structure on the metal layer surrounding the inverted trapezoid microstructures of the inner wall of the substrate; spin-coating a molten wax and cooling down to room temperature, and filling the solid wax into micron-level pores between the inverted trapezoid structures; spin-coating a positive photoresist and performing ultraviolet lithography; g. draining the solid wax out of the micron-level pores to obtain a substrate with an ultra-hydrophobic surface structure; and assembling the substrate to obtain an ultra-hydrophobic easily-releasable concrete test mould.

### TECHNICAL FIELD

The present disclosure relates to the field of concrete test moulds, and in particular to an easily-releasable concrete test mould with an inner wall having ultra-hydrophobic/ultra-smooth performance and a preparation method of the easily-releasable concrete test mould.

### BACKGROUND

Concrete usually refers to an artificial stone formed by adding a given amount of water into a mixture made with a cement as a cementitious material and sands or gravels as an aggregate and then subjecting the mixture to even mixing, compression formation and curing and hardening, and thus this stone is a common civil engineering composite material. In practical applications of the concrete, the strength and durability of the concrete are key factors affecting the engineering quality. Therefore, before commencement of the works, it is very important to perform strength test on the concrete by using a standard concrete test block.

A concrete test mould is a mould for preparing a standard concrete test block for testing a mechanical strength and a durability of the concrete. The concrete test moulds mainly include a concrete compression test mould, a concrete bending test mould, a concrete axial compression test mould, a concrete axial tension test mould and a concrete split tension test mould and the like. At present, the common concrete test moulds include two types. One type is an integrated concrete test mould formed into one-piece by fixedly connecting four vertical plates and one bottom plate, where such moulds are mostly made of plastic; the other type is a detachable concrete test mould formed by assembling a bottom formwork, side formworks, a diaphragm shaft, support eye bolts and butterfly nuts and the like, where such moulds are mostly made of cast iron or steel.

During preparation of a concrete test block, a cementitious hydration product may be generated in the cement hydration process, which increases a frictional force between the concrete and an inner wall of the mould. Thus, the concrete may be easily adhered to the inner wall of the mould, which makes the concrete mould release difficult, and even brings damage to the concrete test block released from the mould.

In order to address the problem of difficulty in release of the formed concrete test block from the mould, the following treatment manners may be employed in the prior arts.

(1) A detachable concrete mould is used. But, there is still a large friction between the formwork surfaces of the detachable concrete mould and the concrete. During mould release, the concrete may be easily adhered to the formwork surfaces of the mould, leading to incomplete concrete test block released from the mould. Further, the detachable mould needs to be mounted before each use, leading to a lower working efficiency. Moreover, the residual concrete adhered to the formwork surfaces of the mould should be cleaned in time, wasting manpower and materials.

(2) A release agent is applied to an inner wall of the mould. During preparation of a concrete test block, a release agent needs to be applied to the inner wall of the mould in advance, lowering the working efficiency. In addition, the release agent may enable the surface of the concrete to have a dull color and easily absorb bubbles. Further, the tension of the surfaces of the bubbles is increased, and the bubbles are difficult to break and drain. Thus, a large number of bubble cavities may be left on the surfaces of the concrete. Furthermore, the release agents are mostly an oily liquid which may absorb impurities during storage, bringing inconveniences to the cleaning of the mould.

(3) The concrete release from the mould is performed by using a release tool or by beating. This manner can easily damage the concrete test block or the mould itself and lower the working efficiency.

### SUMMARY

For the above technical problems, the present disclosure provides an easily-releasable concrete test mould with an inner wall having ultra-hydrophobic performance and a preparation method of the easily-releasable concrete test mould.

The technical solutions employed in the present disclosure are described below.

There is provided an easily-releasable concrete test mould with an inner wall having ultra-hydrophobic performance, which includes four vertical plates and one bottom plate. Inner walls of the vertical plates and the bottom plate are all provided with ultra-hydrophobic surface structure.

Preferably, the ultra-hydrophobic surface structure is a micro-nano structure.

There is provided a preparation method of the easily-releasable concrete test mould with the inner wall having the ultra-hydrophobic performance, which includes the following steps:
a. spin-coating a negative photoresist and obtaining a substrate with an inner wall having inverted-trapezoid microstructures by ultraviolet lithography;
b. depositing a metal layer by vacuum evaporation;
performing metal deposition on the substrate with the inverted-trapezoid microstructures; after completing the metal deposition, taking out the metal-layer-evaporated substrate with the inverted trapezoid microstructures;
c. removing the metal layer on an upper surface of the inverted trapezoid microstructures of the inner wall of the substrate;
d. by using chemical immersion, obtaining a micro-nano hierarchical structure on the metal layer surrounding the inverted trapezoid microstructures of the inner wall of the substrate;
e. on the substrate treated at step d, spin-coating a molten wax and cooling down to room temperature, and filling the solid wax into micron-level pores between the inverted trapezoid structures;
f. spin-coating a positive photoresist and performing ultraviolet lithography;
g. draining the solid wax out of the micron-level pores to obtain a substrate with an ultra-hydrophobic surface structure;
h. assembling the substrate to obtain an ultra-hydrophobic easily-releasable concrete test mould.

Preferably, the step a specifically includes the following steps:
a1. with a vertical plate or a bottom plate as the substrate, cleaning the substrate by using acetone, ethanol and deionized water sequentially;
a2. spin-coating one layer of negative photoresist on the surface of the inner wall of the substrate;
a3. performing first inclined ultraviolet lithography by using an ultraviolet light source;
a4. performing second inclined ultraviolet lithography by rotating the ultraviolet light source 180°;
a5. after the lithography is completed, immediately placing the substrate into a developing solution matching the negative photoresist for development and then cleaning the substrate with deionized water and drying to obtain a substrate with the inner wall having the inverted-trapezoid microstructures.

Preferably, when the inclined ultraviolet lithography is performed, one reflector opposed to the ultraviolet light source is disposed obliquely such that the ultraviolet light is obliquely irradiated onto the ultraviolet photoresist to complete the first ultraviolet lithography; next, the ultraviolet light source and the reflector are rotated 180° synchronously to perform the second ultraviolet lithography.

Preferably, in the step b, the evaporated metal layer is a metal layer of Mg, Zn, Cu or Al.

Preferably, in the step c, the metal layer on the upper surface of the inverted trapezoid microstructures is removed by chemical etching;
firstly a nitric acid solution is prepared and then the substrate with the side of the inverted trapezoid structures horizontally facing down is placed and then translated slowly downward; when the substrate just comes into contact with the nitric acid solution, the substrate is kept stationary to ensure the metal layer on the upper surface of the inverted trapezoid microstructures is in contact with the nitric acid solution while the metal layer on side surfaces is not in contact with the nitric acid solution; after reaction, the substrate is cleaned with deionized water and dried.

Preferably, in the step d, the substrate is placed into a silver nitrate solution or copper chloride solution for reaction and then taken out, and then cleaned with deionized water and then dried in the air, so as to obtain a micro-nano structure on the metal layer on the side surfaces of the inverted trapezoid structures.

Specifically, if the evaporated metal is a metal Cu, Mg or Zn or the like, the substrate is placed into the silver nitrate solution with a concentration of 0.01 to 0.1 mol/L for reaction of 1 to 10 min, and then slowly taken out and then cleaned with deionized water and then dried in the air, so as to obtain a dendritic micro-nano hierarchical structure on the metal layer on the side surfaces of the inverted trapezoid structures.

If the evaporated metal is Al, the substrate is placed into the copper chloride solution with a concentration of 1 to 2 mol/L (a hydrochloric acid solution with a concentration of 1 to 2 mol/L) for reaction of 60 s and then slowly taken out, and immediately cleaned ultrasonically with deionized water and dried in the air, so as to obtain a micro-nano stepped structure on the metal layer on the side surfaces of the inverted trapezoid structures.

Preferably, after the micro-nano structure is obtained on the metal layer on the side surfaces of the inverted trapezoid structures, the method further includes a low surface energy modification step: placing into a mixed solution of stearic acid and ethanol the substrate with the micro-nano structure obtained on the metal layer on the side surfaces of the inverted trapezoid structures to perform hydrophobic modification treatment, and then, cleaning the substrate with deionized water and then drying so as to obtain an ultra-hydrophobic micro-nano structure on the micron-level inverted trapezoid inner surface.

Preferably, in the step g, the wax in the micron-level pores is completely drained out by ultrasonic vibration. Specifically, the substrate subjected to the second ultraviolet lithography is placed into an ultrasonic cleaner; then the ultrasonic cleaner is started to gradually melt the wax in the microstructure (between the inverted trapezoid structures) so as to drain out the wax along with water under the action of the ultrasonic vibration.

Another object of the present disclosure is to provide an easily-releasable concrete test mould with an inner wall having ultra-hydrophobic/ultra-smooth performance and a preparation method of the easily-releasable concrete test mould.

There is provided an easily-releasable concrete test mould with an inner wall having ultra-hydrophobic/ultra-smooth performance, which includes four vertical plates and one bottom plate. Inner walls of the vertical plates and the bottom plate are all provided with a micro-nano structure and a lubricant is injected into pores of the micro-nano structure. The preparation method of the above easily-releasable concrete test mould with the inner wall having ultra-hydrophobic/ultra-smooth performance is also implemented by steps a to g, with the difference in that the method further includes a step j: a lubricant is injected into the substrate with an ultra-hydrophobic surface structure such that all pores are filled up to obtain an ultra-smooth surface. Thus, the above easily-releasable concrete test mould with the inner wall having ultra-hydrophobic/ultra-smooth performance can be obtained by assembling the substrate.

A third object of the present disclosure is to provide a preparation method of the easily-releasable concrete test mould with the inner wall having ultra-hydrophobic performance, which includes the following steps:

The above steps a to e are repeated.

Then, the solid wax is filled, and the positive photoresist is not spin-coated but aluminum is deposited by vacuum evaporation, and then anodized to obtain a porous metal aluminum surface, and finally, the wax in the micron-level pores is completely drained out by ultrasonic vibration so as to obtain an ultra-hydrophobic surface.

In the above method, depositing aluminum by vacuum evaporation specifically includes the following steps:
fixing the substrate onto a substrate platform, and placing an aluminum target material into an evaporation boat; then setting parameters and starting deposition operation;
after the deposition, taking out an aluminum-plated substrate.

In the above method, the anodization may specifically include the following steps:

Anodization is performed on the aluminum-plated substrate in a phosphoric acid solution with a concentration of 0.1 to 0.5 mol/L; with the aluminum-plated substrate as an anode and the stainless steel as a cathode, a distance between the electrodes is set to 20 mm; an anodization voltage is set to 120V, and anodization operation is started at an initial temperature of 50° C.; the anodization lasts for 1 to 5 min, and then, the aluminum-plated substrate subjected to anodization is taken out, and cleaned with deionized water and dried in the air so as to obtain an anodized aluminum with a porous structure.

In the above method, after the anodization is completed, the following treatment step is also included:
placing the anodized aluminum with the porous structure is placed into a mixed solution of stearic acid and ethanol to perform hydrophobic modification treatment.

In the above method, the step of draining out the wax by ultrasonic vibration includes:
placing the anodized aluminum substrate with the porous structure into the ultrasonic cleaner; starting the ultrasonic cleaner to gradually melt the wax in the microstructure and drain it out along with water under the action of the ultrasonic vibration.

A fourth object of the present disclosure is to provide a preparation method of the easily-releasable concrete test mould with the inner wall having ultra-hydrophobic/ultra-smooth performance, which is implemented in the above steps, with the difference in that the method further includes the following step: a lubricant is injected into the substrate with an ultra-hydrophobic surface structure such that all pores are filled up to obtain an ultra-smooth surface. Thus, the above easily-releasable concrete test mould with the inner wall having ultra-hydrophobic/ultra-smooth performance can be obtained by assembling the substrate.

The present disclosure has the following beneficial effects:

(1) Firstly, the lithography technology, the vacuum evaporation deposition technology and chemical immersion method are combined and a lubricant is filled, so as to prepare an ultra-hydrophobic/ultra-smooth surface on the inner wall of the concrete mould. Due to the low adhesion of the ultra-hydrophobic surface, the adhesiveness between the concrete and the inner wall of the mould can be reduced, such that the concrete can be easily released from the inner wall of the concrete test mould, thus realizing intact and complete release of the concrete from the mould.

(2) The lubricant injected into the micro-nano structure has an ultra-smooth performance, which further reduces adhesiveness between the concrete and the inner wall of the concrete test mould. In this way, the concrete can be easily released from the mould without damaging the concrete test block.

(3) Since the lubricant is contained in the micro-nano structure, there is no need to apply a release agent before use, thus increasing the working efficiency.

(4) The micron-level inverted trapezoid structure prepared is a polymer with resilience and hence can be compressed under the weight of the concrete poured and therefore, the lubricant stored in the micro-nano structure can be squeezed into the porous surface.

(5) The prepared micron-level inverted trapezoid structure and the micro-nano structure attached to the surface of the micro-structure can lock up the lubricant and reduce the loss of the lubricant, and thus, the concrete test mould has good durability.

(6) The ultra-hydrophobic/ultra-smooth surface has self-cleaning performance which can reduce the residual concrete adhered to the inner wall of the concrete test mould. Thus, the inner wall of the mould can be kept clean, and the routine maintenance and cleaning work can be reduced, and hence, the working efficiency can be improved.

(7) In the coarse structure with the ultra-hydrophobic/ultra-smooth surface are air and lubricant, and thus external corrosive mediums can be effectively isolated. If the concrete test mould is made of metal, the ultra-hydrophobic surface has good anti-corrosion effect on the substrate, further increasing the service life of the concrete test mould.

### BRIEF DESCRIPTIONS OF THE DRAWINGS

FIG. 1 is a flowchart of preparing an ultra-hydrophobic surface in an embodiment 4.

FIG. 2 is a top view of an ultra-hydrophobic surface.

FIG. 3 is a flowchart of preparing an ultra-hydrophobic/ultra-smooth surface in an embodiment 5.

FIG. 4 is a top view of an ultra-hydrophobic/ultra-smooth surface.

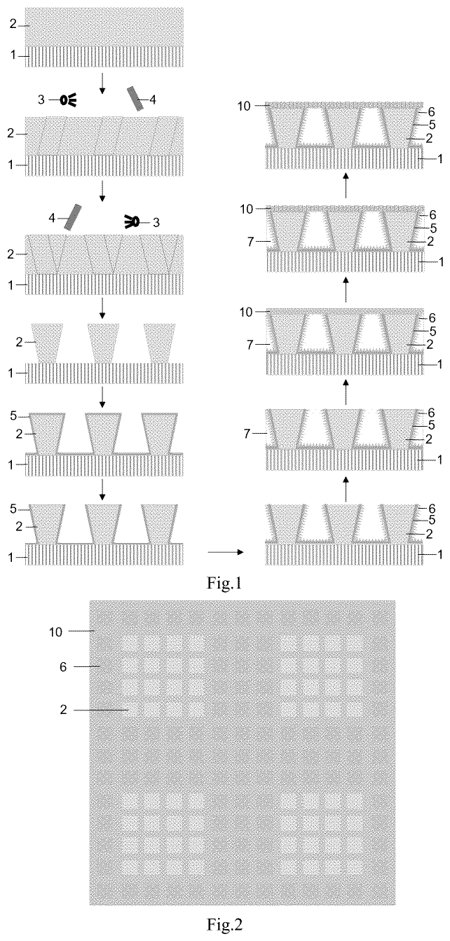

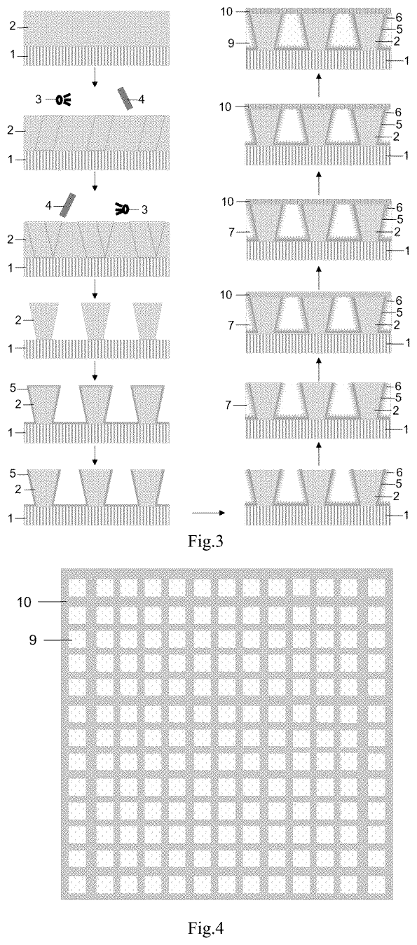

Numerals of the drawings are described below: 1. concrete test mould plate surface, 2. negative photoresist, 3. ultraviolet light source, 4. reflector, 5. metal layer, 6. coarse micro-nano structure, 7. wax, 9. lubricant and 10. metal aluminum.

### DETAILED DESCRIPTIONS OF EMBODIMENTS

In order to address the problems of difficulty in release of the concrete test mould, large adhesiveness between the mould plate surface and the concrete, and ease of damaging the concrete during release, the present disclosure provides an easily-releasable concrete test mould with an inner wall having an ultra-hydrophobic/ultra-smooth surface.

1. The lithography technology, the vacuum evaporation deposition technology and chemical immersion method are combined and a lubricant is filled, so as to prepare an ultra-hydrophobic/ultra-smooth surface on the inner wall of the concrete test mould. In this way, an easily-releasable concrete test mould with a low-adhesiveness inner wall is obtained.

2. The inner wall of the concrete test mould has ultra-hydrophobic performance which reduces the adhesiveness of the inner wall of the concrete test mould, and thus, the concrete can be smoothly released from the mould during release while the concrete shape is intact.

3. The micro-nano structure of the inner wall of the concrete test mould helps to lock up the lubricant and reduce the loss of the lubricant. Furthermore, since the micro-nano structure is polymer with a resilience, and thus the lubricant stored in the micron-level structure can be squeezed out under the action of the poured concrete, achieving the lubrication effect and helping release of the concrete.

4. The concrete test mould has good self-cleaning performance, which reduces the residual concrete adhered to the inner wall of the concrete test mould, increasing the daily cleaning efficiency.

The present disclosure provides an easily-releasable concrete test mould with an inner wall having ultra-hydrophobic/ultra-smooth performance, which includes four vertical plates and one bottom plate. Inner walls of the vertical plates and the bottom plate are all provided with an ultra-hydrophobic/ultra-smooth surface.

The ultra-hydrophobic/ultra-smooth surface can be obtained in the following steps.

1) Firstly, one layer of negative photoresist is spin-coated on surfaces of the vertical plates and the bottom plate by using the lithography technology, and under an inclined light source, ultraviolet lithography is performed twice to obtain an inverted trapezoid micro-structure.

2) Then, by using vacuum evaporation deposition technology, a metal layer is deposited on the surface of the inverted trapezoid micro-structure.

3) By using chemical etching, the metal layer on an upper surface of the inverted trapezoid structures is removed.

4) By immersion in a chemical solution, a micro-nano hierarchical structure is obtained on the inverted trapezoid surface, and further, by immersion in a low-surface energy solution, low-surface energy modification is performed on the obtained micro-nano hierarchical structure.

5) A molten wax is spin-coated on the surface of the substrate to fill up the pores of the micro-structure.

6) After the wax is cured, one layer of positive photoresist is spin-coated on the surface to perform conventional ultraviolet lithography so as to obtain one layer of micron-level porous structure.

7) The substrate subjected to the second ultraviolet lithography is placed into an ultrasonic cleaner for ultrasonic cleaning, such that the wax in the micro-structure is drained out along with water under the action of the ultrasonic vibration, so as to obtain an ultra-hydrophobic surface.

8) A lubricant is injected into the micro-nano structure to fill up all pores, so as to obtain an ultra-smooth surface.

The present disclosure will be further described below with specific embodiments.

### Embodiment 1

There is provided a preparation method of an easily-releasable concrete test mould with an inner wall having ultra-hydrophobic performance, which includes the following steps.

a. A negative photoresist is spin-coated and a substrate with an inner wall having inverted-trapezoid microstructures is obtained by ultraviolet lithography.

The step a specifically includes the following steps:
a1. with a vertical plate or a bottom plate as the substrate, cleaning the substrate by using acetone, ethanol and deionized water sequentially;
a2. spin-coating one layer of negative photoresist on the surface of the inner wall of the substrate;
a3. performing first inclined ultraviolet lithography by using an ultraviolet light source;
a4. performing second inclined ultraviolet lithography by rotating the ultraviolet light source 180°;
a5. after the lithography is completed, immediately placing the substrate into a developing solution matching the negative photoresist for development and then cleaning the substrate with deionized water and drying to obtain a substrate with the inner wall having the inverted-trapezoid microstructures.

In the above steps, when the inclined ultraviolet lithography is performed, one reflector opposed to the ultraviolet light source is disposed obliquely as shown in FIGS. 1 and 3, such that the ultraviolet light is obliquely irradiated onto the ultraviolet photoresist to complete the first ultraviolet lithography; next, the ultraviolet light source and the reflector are rotated 180° synchronously to perform the second ultraviolet lithography.

b. A metal layer is deposited by vacuum evaporation.

Metal deposition is performed on the substrate with the inverted-trapezoid microstructures; after completing the metal deposition, the metal-layer-evaporated substrate with the inverted trapezoid microstructures is taken out.

The evaporated metal layer is a metal layer of Mg, Zn, or Cu.

c. The metal layer on an upper surface of the inverted trapezoid microstructures of the inner wall of the substrate is removed.

Specifically, the metal layer on the upper surface of the inverted trapezoid microstructures is removed by chemical etching.

Firstly a nitric acid solution of 6 mol/L is prepared and then the substrate with the side of the inverted trapezoid structures horizontally facing down is placed and then translated slowly downward; when the substrate just comes into contact with the nitric acid solution, the substrate is kept stationary to ensure the metal layer on the upper surface of the inverted trapezoid microstructures is in contact with the nitric acid solution while the metal layer on side surfaces is not in contact with the nitric acid solution; after reaction of 5 s, the substrate is cleaned with deionized water and dried.

d. By using chemical immersion, a micro-nano hierarchical structure is obtained on the metal layer surrounding the inverted trapezoid microstructures of the inner wall of the substrate.

Specifically, the substrate is placed into a silver nitrate solution of 0.01 mol/L for reaction of 5 min and then taken out, and then cleaned with deionized water and then dried in the air, so as to obtain a dendritic micro-nano hierarchical structure on the metal layer on the side surfaces of the inverted trapezoid structures.

Then, low surface energy modification is performed: to a mixed solution of stearic acid and ethanol, the substrate with the micro-nano structure obtained on the metal layer on the side surfaces of the inverted trapezoid structures is placed and held for 60 minutes to perform hydrophobic modification treatment, where the concentration of stearic acid is 0.01 mol/L; and then, the substrate is cleaned with deionized water and then dried so as to obtain an ultra-hydrophobic micro-nano hierarchical structure on the micron-level inverted trapezoid inner surface.

e. On the substrate treated at step d, a molten wax is spin-coated and cooled down to room temperature, and then the solid wax filled into micron-level pores between the inverted trapezoid structures.

f. A positive photoresist is spin-coated to perform conventional ultraviolet lithography with a pre-designed lithography pattern. After the lithography is completed, the substrate is immediately placed into a developing solution matching the positive photoresist for development, and then cleaned with deionized water and then dried.

The above lithography pattern may be any one of square, rectangle, rhombus, circle, and triangle and the like.

g. The solid wax in the micron-level pores is drained out to obtain a substrate with an ultra-hydrophobic surface structure. Specifically, the wax in the micron-level pores can be completely drained out by ultrasonic vibration.

The step of draining the wax includes the following steps: the substrate subjected to the second ultraviolet lithography is placed into the ultrasonic cleaner; the temperature of the ultrasonic cleaner is set to 65° C. and the time is set to 30 min; the ultrasonic cleaner is started to gradually melt the wax in the microstructure to drain it out along with water under the action of the ultrasonic vibration.

h. The substrate is assembled to obtain an ultra-hydrophobic easily-releasable concrete test mould.

The body of the above substrate may be a plastic or steel substrate or the like.

The ultra-hydrophobic surface obtained in this embodiment has the following advantages:

(1) Due to the low adhesion of the ultra-hydrophobic surface, the adhesiveness between the concrete and the inner wall of the mould can be reduced, such that the concrete can be easily released from the inner wall of the concrete test mould, thus realizing intact and complete release of the concrete from the mould.

(2) The ultra-hydrophobic surface has self-cleaning performance which can reduce the residual concrete adhered to the inner wall of the concrete test mould. Thus, the inner wall of the mould can be kept clean, and the routine maintenance and cleaning work can be reduced, and hence, the working efficiency can be improved.

(3) The coarse structure with an ultra-hydrophobic surface contains one layer of air, which reduces a contact area of the external medium and the plate surface of the concrete test mould, and further lowers the frictional force between the external substance and the plate surface of the concrete test mould, and hence reduces damage to the inner wall of the concrete test mould during concrete pouring process.

(4) The coarse structure with an ultra-hydrophobic surface contains one layer of air, which can effectively isolate the external corrosive mediums. If the concrete test mould is made of metal, the ultra-hydrophobic surface has good anticorrosion effect on the substrate, further increasing the service life of the concrete test mould.

### Embodiment 2

The preparation method is the same as in the embodiment 1 with the difference in that: a lubricant is injected into the substrate with an ultra-hydrophobic surface structure obtained in the step g in the embodiment 1 to fill up all the pores so as to obtain an ultra-smooth surface. Then, the substrate is assembled to obtain an easily-releasable concrete test mould with ultra-hydrophobic/ultra-smooth performance.

The ultra-hydrophobic/ultra-smooth surface obtained by injecting a lubricant in this embodiment has the following advantages:

(1) The lubricant injected into the micro-nano structure has an ultra-smooth performance which further reduces the adhesiveness between the concrete and the inner wall of the concrete test mould, such that the concrete can be easily released from the mould, without damaging the concrete test block.

(2) Since the micro-nano structure contains a lubricant, there is no need to apply a release agent in advance before use, thus increasing the working efficiency.

(3) The micron-level inverted trapezoid structure prepared is a polymer with resilience and hence can be compressed under the weight of the concrete poured and therefore, the lubricant stored in the micro-nano structure can be squeezed into the porous surface.

(4) The prepared micron-level inverted trapezoid structure and the micro-nano structure attached to the surface of the micro-structure can lock up the lubricant and reduce the loss of the lubricant, and thus, the concrete test mould has good durability.

(5) The ultra-smooth surface has self-cleaning performance which can reduce the residual concrete adhered to the inner wall of the concrete test mould. Thus, the inner wall of the mould can be kept clean, and the routine maintenance and cleaning work can be reduced, and hence, the working efficiency can be improved.

(6) In the coarse structure with the ultra-smooth surface is a lubricant, and thus external corrosive mediums can be effectively isolated. If the concrete test mould is made of metal, the ultra-hydrophobic surface has good anti-corrosion effect on the substrate, further increasing the service life of the concrete test mould.

(7) The coarse structure with the ultra-smooth surface contains one layer of lubricant, and thus external corrosive mediums can be effectively isolated. If the concrete test mould is made of metal, the ultra-smooth surface has good anti-corrosion effect on the substrate, further increasing the service life of the concrete test mould.

(8) The coarse structure with an ultra-smooth surface contains one layer of lubricant, which reduces a frictional force between the external medium and the plate surface of the concrete test mould, and hence reduces damage to the inner wall of the concrete test mould during concrete pouring process.

### Embodiment 3

The preparation method is the same as in the embodiment 1 with the difference in that: in the step b, the evaporated metal layer is a metal layer of Al; correspondingly, in the step d, the substrate is placed into a copper chloride solution with a concentration of 1 mol/L (or hydrochloric acid with a concentration of 2 mol/L) for reaction of 60 s, and then slowly taken out, and immediately cleaned ultrasonically with deionized water and then dried in the air, so as to obtain a micro-nano stepped structure on the metal layer on the side surfaces of the inverted trapezoid structures.

### Embodiment 4

There is provided a preparation method of an easily-releasable concrete test mould with an inner wall having ultra-hydrophobic performance, which includes the following steps.

a. A negative photoresist is spin-coated and a substrate with an inner wall having inverted-trapezoid microstructures is obtained by ultraviolet lithography.

The step a specifically includes the following steps:
a1. with a vertical plate or a bottom plate as the substrate, cleaning the substrate by using acetone, ethanol and deionized water sequentially;
a2. spin-coating one layer of negative photoresist on the surface of the inner wall of the substrate;
a3. performing first inclined ultraviolet lithography by using an ultraviolet light source;
a4. performing second inclined ultraviolet lithography by rotating the ultraviolet light source 180°;
a5. after the lithography is completed, immediately placing the substrate into a developing solution matching the negative photoresist for development and then cleaning the substrate with deionized water and drying to obtain a substrate with the inner wall having the inverted-trapezoid microstructures.

In the above steps, when the inclined ultraviolet lithography is performed, one reflector opposed to the ultraviolet light source is disposed obliquely as shown in FIGS. 1 and 3, such that the ultraviolet light is obliquely irradiated onto the ultraviolet photoresist to complete the first ultraviolet lithography; next, the ultraviolet light source and the reflector are rotated 180° synchronously to perform the second ultraviolet lithography.

b. A metal layer is deposited by vacuum evaporation.

Metal deposition is performed on the substrate with the inverted-trapezoid microstructures; after completing the metal deposition, the metal-layer-evaporated substrate with the inverted trapezoid microstructures is taken out.

The evaporated metal layer is a metal layer of Mg, Zn, or Cu.

c. The metal layer on an upper surface of the inverted trapezoid microstructures of the inner wall of the substrate is removed.

Specifically, the metal layer on the upper surface of the inverted trapezoid microstructures is removed by chemical etching.

Firstly a nitric acid solution of 6 mol/L is prepared and then the substrate with the side of the inverted trapezoid structures horizontally facing down is placed and then translated slowly downward; when the substrate just comes into contact with the nitric acid solution, the substrate is kept stationary to ensure the metal layer on the upper surface of the inverted trapezoid microstructures is in contact with the nitric acid solution while the metal layer on side surfaces is not in contact with the nitric acid solution; after reaction of 5 s, the substrate is cleaned with deionized water and dried.

d. By using chemical immersion, a micro-nano hierarchical structure is obtained on the metal layer surrounding the inverted trapezoid microstructures of the inner wall of the substrate.

Specifically, the substrate is placed into a silver nitrate solution of 0.01 mol/L for reaction of 5 min and then taken out, and then cleaned with deionized water and then dried in the air, so as to obtain a dendritic micro-nano hierarchical structure on the metal layer on the side surfaces of the inverted trapezoid structures.

Then, low surface energy modification is performed: to a mixed solution of stearic acid and ethanol, the substrate with the micro-nano structure obtained on the metal layer on the side surfaces of the inverted trapezoid structures is placed and held for 60 minutes to perform hydrophobic modification treatment, where the concentration of stearic acid is 0.01 mol/L; and then, the substrate is cleaned with deionized water and then dried so as to obtain an ultra-hydrophobic micro-nano hierarchical structure on the micron-level inverted trapezoid inner surface.

e. On the substrate treated at step d, a molten wax is spin-coated and cooled down to room temperature, and then the solid wax filled into micron-level pores between the inverted trapezoid structures.

f. Aluminum is deposited by vacuum evaporation and then anodized to obtain a porous metal aluminum surface.

Depositing aluminum by vacuum evaporation specifically includes the following steps:
fixing the substrate onto a substrate platform, and placing an aluminum target material into an evaporation boat; then setting parameters and starting deposition operation;
after the deposition, taking out an aluminum-plated substrate.

The anodization may specifically include the following steps:

Anodization is performed on the aluminum-plated substrate in a phosphoric acid solution with a concentration of 0.25 mol/L; with the aluminum-plated substrate as an anode and the stainless steel as a cathode, a distance between the electrodes is set to 20 mm; an anodization voltage is set to 120V, and anodization operation is started at an initial temperature of 50° C.; the anodization lasts for 1 min, and then, the aluminum-plated substrate subjected to anodization is taken out, and cleaned with deionized water and dried in the air so as to obtain an anodized aluminum with a porous structure.

After the anodization, the substrate is then placed into a 0.01 mol/L mixed solution of stearic acid (or silane) and ethanol and held for 60 min to perform hydrophobic modification treatment.

g. The solid wax in the micron-level pores is drained out to obtain a substrate with an ultra-hydrophobic surface structure. Specifically, the wax in the micron-level pores can be completely drained out by ultrasonic vibration.

The step of draining the wax includes the following steps: the substrate subjected to the second ultraviolet lithography is placed into the ultrasonic cleaner; the temperature of the ultrasonic cleaner is set to 65° C. and the time is set to 30 min; the ultrasonic cleaner is started to gradually melt the wax in the microstructure to drain it out along with water under the action of the ultrasonic vibration.

h. The substrate is assembled to obtain an easily-releasable concrete test mould with ultra-hydrophobic performance.

### Embodiment 5

The preparation method is the same as in the embodiment 4 with the difference in that: a lubricant is injected into the substrate with an ultra-hydrophobic surface structure obtained in the step g in the embodiment 4 to fill up all the pores, so as to obtain an ultra-smooth surface. Then, the substrate is assembled to obtain an easily-releasable concrete test mould with an ultra-hydrophobic/ultra-smooth performance.

1. An easily-releasable concrete test mould with an inner wall having ultra-hydrophobic performance, comprising four vertical plates and one bottom plate, wherein inner walls of the vertical plates and the bottom plate are all provided with an ultra-hydrophobic surface structure.

2. The easily-releasable concrete test mould of claim 1, wherein the ultra-hydrophobic surface structure is a micro-nano-structure.

3. A preparation method of the easily-releasable concrete test mould according to claim 1, comprising the following steps:
a. spin-coating a negative photoresist and obtaining a substrate with an inner wall having inverted-trapezoid microstructures by ultraviolet lithography;
b. depositing a metal layer by vacuum evaporation;
performing metal deposition on the substrate with the inverted-trapezoid microstructures;
after completing the metal deposition, taking out the metal-layer-evaporated substrate with the inverted trapezoid microstructures;
c. removing the metal layer on an upper surface of the inverted trapezoid microstructures of the inner wall of the substrate;
d. by using chemical immersion, obtaining a micro-nano hierarchical structure on the metal layer surrounding the inverted trapezoid microstructures of the inner wall of the substrate;
e. on the substrate treated at step d, spin-coating a molten wax and cooling down to room temperature, and filling the solid wax into micron-level pores between the inverted trapezoid structures;
f. spin-coating a positive photoresist and performing ultraviolet lithography;
g. draining the solid wax out of the micron-level pores to obtain a substrate with an ultra-hydrophobic surface structure;
h. assembling the substrate to obtain an ultra-hydrophobic easily-releasable concrete test mould.

4. The preparation method of claim 3, wherein the step a specifically comprises the following steps:
a1. with a vertical plate or a bottom plate as the substrate, cleaning the substrate by using acetone, ethanol and deionized water sequentially;
a2. spin-coating one layer of negative photoresist on the surface of the inner wall of the substrate;
a3. performing first inclined ultraviolet lithography by using an ultraviolet light source;
a4. performing second inclined ultraviolet lithography by rotating the ultraviolet light source 180°;
a5. after the lithography is completed, immediately placing the substrate into a developing solution matching the negative photoresist for development and then cleaning the substrate with deionized water and drying to obtain a substrate with the inner wall having the inverted-trapezoid microstructures.

5. The preparation method of claim 4, wherein when the inclined ultraviolet lithography is performed, one reflector opposed to the ultraviolet light source is disposed obliquely such that the ultraviolet light is obliquely irradiated onto the ultraviolet photoresist to complete the first ultraviolet lithography; next, the ultraviolet light source and the reflector are rotated 180° synchronously to perform the second ultraviolet lithography.

6. The preparation method of claim 3, wherein in the step b, the evaporated metal layer is a metal layer of Mg, Zn, Cu or Al.

7. The preparation method of claim 3, wherein in the step c, the metal layer on the upper surface of the inverted trapezoid microstructures is removed by chemical etching;
firstly a nitric acid solution is prepared and then the substrate with the side of the inverted trapezoid structures horizontally facing down is placed and then translated slowly downward; when the substrate just comes into contact with the nitric acid solution, the substrate is kept stationary to ensure the metal layer on the upper surface of the inverted trapezoid microstructures is in contact with the nitric acid solution while the metal layer on side surfaces is not in contact with the nitric acid solution; after reaction, the substrate is cleaned with deionized water and dried.

8. The preparation method of claim 3, wherein in step d, the substrate is placed into a silver nitrate solution or copper chloride solution for reaction and then taken out, and then cleaned with deionized water and then dried in the air, so as to obtain a micro-nano structure on the metal layer on the side surfaces of the inverted trapezoid structures.

9. The preparation method of claim 8, further comprising a low surface energy modification step: placing into a mixed solution of stearic acid and ethanol the substrate with the micro-nano structure obtained on the metal layer on the side surfaces of the inverted trapezoid structures to perform hydrophobic modification treatment, and then, cleaning the substrate with deionized water and then drying so as to obtain an ultra-hydrophobic micro-nano structure on the micron-level inverted trapezoid inner surface.

10. The preparation method of claim 3, wherein in the step g, the wax in the micron-level pores is completely drained out by ultrasonic vibration.
